(19) United States
(12) Patent Application Publication
(10) Pub. No.: US 2012/0214103 A1
(43) Pub. Date: Aug. 23, 2012

(54) METHOD FOR FABRICATING SEMICONDUCTOR DEVICES WITH FINE PATTERNS

(75) Inventors: Ming Kang Wei, Taoyuan City (TW); Pei Lin Huang, Taipei City (TW); Yi Ming Wang, Taoyuan City (TW); Ying Chung Tseng, Xinzhuang City (TW)

(73) Assignee: NANYA TECHNOLOGY CORP., Kueishan (TW)

(21) Appl. No.: 13/030,533

(22) Filed: Feb. 18, 2011

(51) Int. Cl. G03F 7/20

(52) U.S. Cl. 430/313; 430/319

(57) ABSTRACT

A method for fabricating semiconductor devices with fine patterns includes the steps of providing a semiconductor substrate, forming a first photoresist layer on the semiconductor substrate, forming a second photoresist layer on the first photoresist layer, and performing an exposing process to change the state of at least one first portion of the first photoresist layer and the state of at least one second portion of the second photoresist layer. The conventional double patterning technique requires that the exposure processes be performed twice, which requires very precise alignment between the two exposure processes. In contrast, the embodiment of the present invention can perform the double patterning process with only one exposure process without requiring the precise alignment between the two exposure processes.

### 1. TECHNICAL FIELD

The present invention relates to a method for fabricating semiconductor devices with fine patterns, and more particularly, to a method for fabricating semiconductor devices with fine patterns by incorporating two photoresist layers with one exposing process to achieve high integration.

### 2. BACKGROUND

As the integration density of semiconductor devices increases, the lithographic process needs a higher resolution to meet the precision requirement of the semiconductor device. Photolithography process is typically used to fabricate electronic and optoelectronic devices on a semiconductor substrate and photoresist patterns prepared by the photolithography process are used as masks in etching or ion implantation. Therefore, the fineness of the photoresist patterns is a very important factor in determining the degree of integration.

One method to increase resolution is to use a light source with a shorter wavelength as the exposure light source. For example, a krypton fluoride (KrF) laser is used to provide deep UV light with a wavelength of 248 nanometers and an argon fluoride (ArF) laser is used to provide deep UV light with a wavelength of 193 nanometers. Another method of forming such fine photoresist patterns on the semiconductor substrate is through double patterning technique. In a double patterning process, a pattern from a first exposure may be etched onto a photoresist layer on the semiconductor substrate, and the semiconductor substrate is subsequently recoated with the photoresist layer to form a second pattern and then re-etched to obtain the desired pattern. However, the double patterning technique requires that the exposure process be performed twice, which requires very precise alignment between the two exposure processes.

### SUMMARY

One aspect of the present invention provides a method for fabricating semiconductor devices with fine patterns by incorporating two photoresist layers with one exposing process to achieve high integration.

One embodiment of the present invention provides a method for fabricating semiconductor devices with fine patterns comprising the steps of providing a semiconductor substrate, forming a first photoresist layer on the semiconductor substrate, forming a second photoresist layer on the first photoresist layer, and performing an exposing process to change the state of at least one first portion of the first photoresist layer and the state of at least one second portion of the second photoresist layer.

The conventional double patterning technique requires that the exposure process be performed twice, which requires very precise alignment between the two exposure processes. In contrast, the embodiment of the present invention can perform the double patterning process with only one exposure process without requiring the precise alignment between the two exposure processes.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a cross-sectional view of a semiconductor substrate in accordance with one embodiment of the present invention;

FIG. 2 is a schematic diagram showing an exposing process in accordance with one embodiment of the present invention;

FIG. 3 is a cross-sectional view showing the application of the exposure light 60 in accordance with one embodiment of the present invention;

FIG. 4 is a cross-sectional view showing the application of a first developing process to the second photoresist layer in accordance with one embodiment of the present invention;

FIG. 5 and FIG. 6 are cross-sectional views showing the application of a second developing process to the first photoresist layer in accordance with one embodiment of the present invention; and

FIG. 7 and FIG. 8 are cross-sectional views showing the application of an etching process to the objective layer in accordance with one embodiment of the present invention.

### DETAILED DESCRIPTION

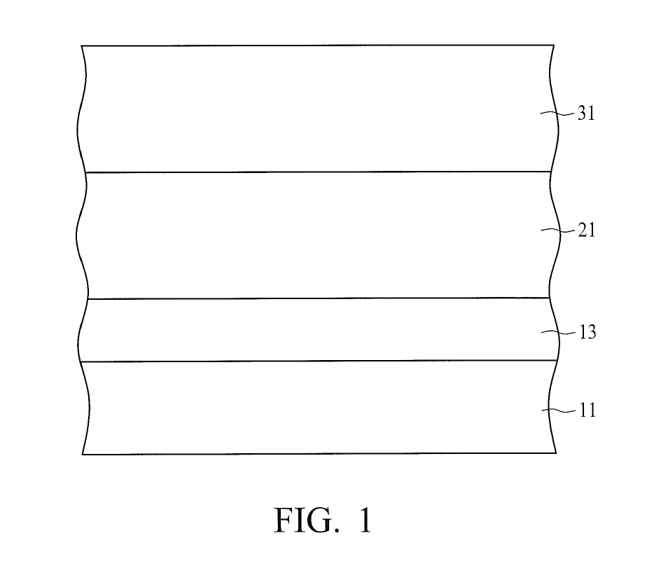

FIG. 1 to FIG. 8 are schematic diagrams showing a method for fabricating a semiconductor device 100 with fine patterns in accordance with one embodiment of the present invention. FIG. 1 is a cross-sectional view of a semiconductor substrate 11 in accordance with one embodiment of the present invention. In one embodiment of the present invention, fabrication processes are performed to form an objective layer 13 such as an oxide layer on the semiconductor substrate 11 such as a silicon wafer. Subsequently, coating processes are performed to form a first photoresist layer 21 on the objective layer 13 and a second photoresist layer 31 on the first photoresist layer 21. In one embodiment of the present invention, the second photoresist layer 31 is formed directly on the first photoresist layer 21, i.e., no intermediate layer is formed between the first photoresist layer 21 and the second photoresist layer 31.

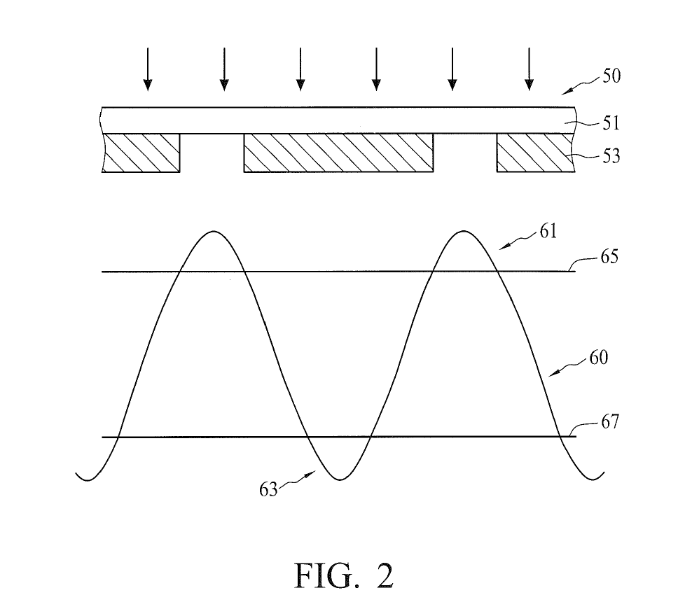

FIG. 2 is a schematic diagram showing an exposing process in accordance with one embodiment of the present invention. In one embodiment of the present invention, an exposure mask 50 is prepared by forming predetermined light screen patterns 53 on a transparent substrate 51, and light beams pass through the exposure mask 50 to form an exposure light 60 with a sinusoidal waveform. In one embodiment of the present invention, the exposure light 60 includes a peak portion 61 with an intensity larger than a threshold intensity 65 of the first photoresist layer 21. In one embodiment of the present invention, the exposure light 60 includes a valley portion 63 with an intensity smaller than a threshold intensity 67 of the second photoresist layer 31.

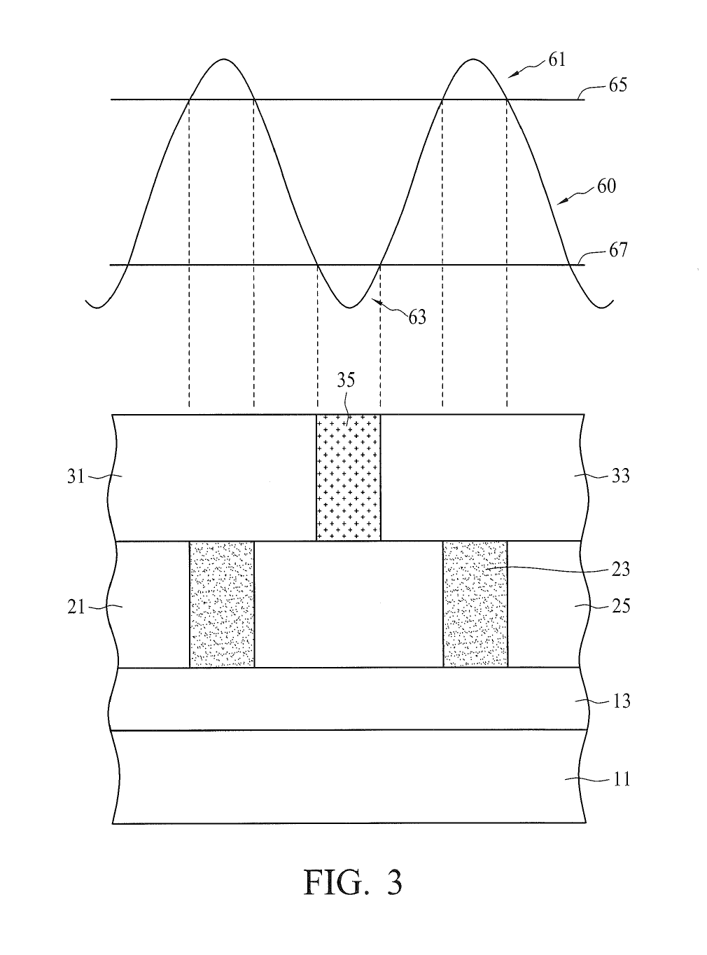

FIG. 3 is a cross-sectional view showing the application of the exposure light 60 in accordance with one embodiment of the present invention. In one embodiment of the present invention, an exposing process is performed by applying the exposure light 60 to both the second photoresist layer 31 and the first photoresist layer 21. In one embodiment of the present invention, the exposure light 60 in the exposing process changes the state of at least one first portion 23 of the first photoresist layer 21 and the state of at least one second portion 33 of the second photoresist layer 31. In one embodiment of the present invention, the at least one second portion 33 of the second photoresist layer 31 covers the at least one first portion 23 of the first photoresist layer 21.

In one embodiment of the present invention, the second photoresist layer 31 is a negative photoresist layer, which originally is soluble in a predetermined developer before the exposing process. The exposure light 60 in the exposing process transforms the portion 33 of the second photoresist layer 31 from a soluble state to a state that is insoluble in the developer, while the other portion 35 of the second photoresist layer 31 remains soluble in the developer. In particular, the portion 35 of the second photoresist layer 31 under the valley portion 63 of the exposure light 60 receives an optical dose smaller than the threshold intensity 67 of the second photoresist layer 31, and therefore the portion 35 of the second photoresist layer 31 under the valley portion 63 of the exposure light 60 remains soluble in the developer; in contrast, the portion 33 of the second photoresist layer 31 not under the valley portion 63 receives an optical dose larger than the threshold intensity 67 of the second photoresist layer 31, and therefore is transformed from a soluble state into a state that is insoluble in the developer.

In one embodiment of the present invention, the first photoresist layer 21 is a positive photoresist layer, which originally is insoluble in a predetermined developer before the exposing process. The exposure light 60 in the exposing process transforms the portion 23 of the first photoresist layer 21 from an insoluble state into a state that is soluble in the developer, while the other portion 25 of the first photoresist layer 21 remains insoluble to the developer. In particular, the portion 23 of the first photoresist layer 21 under the peak portion 61 of the exposure light 60 receives an optical dose larger than the threshold intensity 65 of the first photoresist layer 21, and therefore is transformed from the insoluble state into a state that is soluble in the developer; in contrast, the portion 25 of the first photoresist layer 21 not under the peak portion 61 receives an optical dose smaller than the threshold intensity 65 of the first photoresist layer 21, and therefore remains insoluble in the developer.

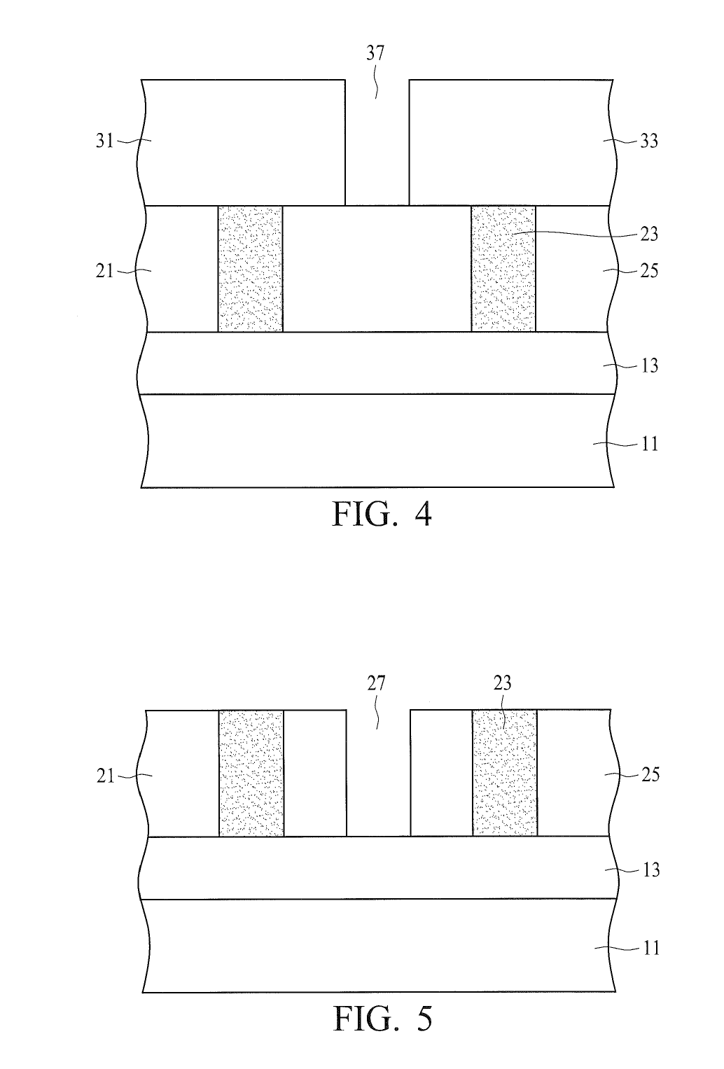

FIG. 4 is a cross-sectional view showing the application of a first developing process to the second photoresist layer 31 in accordance with one embodiment of the present invention. In one embodiment of the present invention, the developer for the second photoresist layer 31 is used to selectively remove the soluble portion 35 of the second photoresist layer 31 under the valley portion 63 so as to form an opening 37 in the second photoresist layer 31.

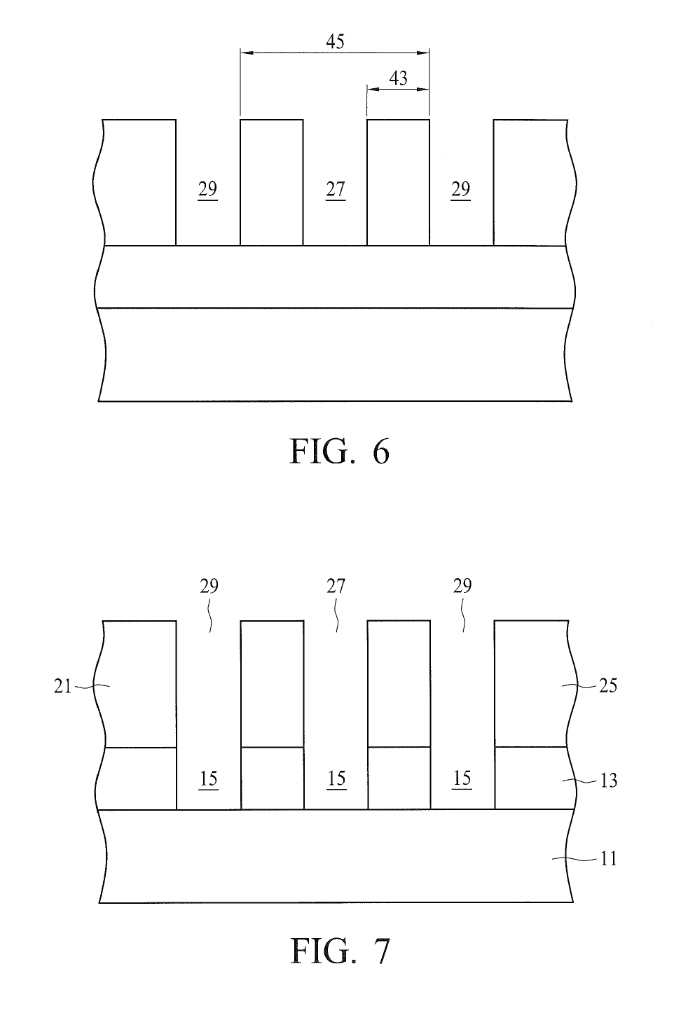

FIG. 5 and FIG. 6 are cross-sectional views showing the application of an etching process to the first photoresist layer 21 in accordance with one embodiment of the present invention. In one embodiment of the present invention, a dry etching process is performed by using the second photoresist layer 31 as the hardmask to remove a portion of the first photoresist layer 21 so as to form an opening 27 under the opening 37, and the second photoresist layer 31 is also removed while the dry etching process is performed, as shown in FIG. 5. Subsequently, the developer for the first photoresist layer 21 is used to selectively remove the soluble portion 23 of the first photoresist layer 21 under the peak portion 61 so as to form an opening 29 in the first photoresist layer 21, as shown in FIG. 6. The openings 29 are formed by the patterning process of the first photoresist layer 21, while the opening 27 is formed by the patterning process of the second photoresist layer 31.

In particular, the space 45 between the openings 29 is obviously larger than the space 43 between the opening 29 and the opening 27. In other words, using the patterning process of the first photoresist layer 21 alone can form the patterns (openings 29) with larger space 45, while using the double patterning process of the first photoresist layer 21 together with the second photoresist layer 31 can form patterns (openings 29 and 27) with smaller space 43.

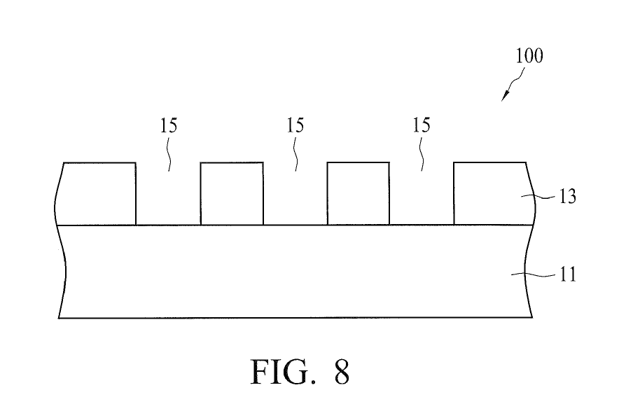

FIG. 7 and FIG. 8 are cross-sectional views showing the application of an etching process to the objective layer 13 in accordance with one embodiment of the present invention. In one embodiment of the present invention, an etching process such as the dry etching process is performed by using the first photoresist layer 21 as the etching mask to selectively remove a portion of the objective layer 13 under the openings 27 and 29 so as to form a plurality of holes in the objective layer 13. Subsequently, the first photoresist layer 21 is then stripped to complete the semiconductor device 100, as shown in FIG. 8. In one embodiment of the present invention, the holes in the objective layer 13 can be contact holes that expose diffusion regions in the semiconductor substrate 11, and the diffusion regions may serve as the source/drain regions of a transistor.

The conventional double patterning technique requires that the exposure processes be performed twice, which requires very precise alignment between the two exposure processes. In contrast, the embodiment of the present invention can perform the double patterning process with only one exposure process without requiring the precise alignment between the two exposure processes.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating semiconductor devices with fine patterns, comprising the steps of:
providing a semiconductor substrate;
forming a first photoresist layer on the semiconductor substrate;
forming a second photoresist layer on the first photoresist layer; and
performing an exposing process to change the state of at least one first portion of the first photoresist layer and the state of at least one second portion of the second photoresist layer.

2. The method for fabricating semiconductor devices with fine patterns of claim 1, wherein the first photoresist layer is a positive photoresist layer.

3. The method for fabricating semiconductor devices with fine patterns of claim 1, wherein the second photoresist layer is a negative photoresist layer.

4. The method for fabricating semiconductor devices with fine patterns of claim 1, wherein the at least one second portion of the second photoresist layer covers the at least one first portion of the first photoresist layer.

5. The method for fabricating semiconductor devices with fine patterns of claim 1, wherein the exposing process transforms the first portion of the first photoresist layer from an insoluble state into a soluble state.

6. The method for fabricating semiconductor devices with fine patterns of claim 1, wherein the exposing process transforms the second portion of the second photoresist layer from a soluble state into an insoluble state.

7. The method for fabricating semiconductor devices with fine patterns of claim 1, wherein after the exposing process, the first photoresist layer comprises at least one first soluble portion, and the second photoresist layer comprises at least one second soluble portion.

8. The method for fabricating semiconductor devices with fine patterns of claim 7, wherein the second soluble portion is not directly above the first soluble portion.

9. The method for fabricating semiconductor devices with fine patterns of claim 7, further comprising a step of performing a developing process to remove the second soluble portion.

10. The method for fabricating semiconductor devices with fine patterns of claim 7, further comprising a step of performing an etching process to remove a portion of the first photoresist layer under the second soluble portion.

11. The method for fabricating semiconductor devices with fine patterns of claim 10, wherein the etching process uses the second photoresist layer as an etching mask.

12. The method for fabricating semiconductor devices with fine patterns of claim 10, further comprising a step of performing a developing process to remove the at least one first portion.

13. The method for fabricating semiconductor devices with fine patterns of claim 1, wherein the exposing process applies an exposure light with a sinusoidal waveform to the second photoresist layer and the first photoresist layer.

14. The method for fabricating semiconductor devices with fine patterns of claim 13, wherein the exposure light includes a peak portion with an intensity larger than a threshold intensity of the first photoresist layer.

15. The method for fabricating semiconductor devices with fine patterns of claim 13, wherein the exposure light includes a valley portion with an intensity smaller than a threshold intensity of the second photoresist layer.

16. The method for fabricating semiconductor devices with fine patterns of claim 1, wherein the at least one first portion is a soluble portion and the at least one second portion is an insoluble portion.

17. The method for fabricating semiconductor devices with fine patterns of claim 1, wherein no intermediate layer is formed between the first photoresist layer and the second photoresist layer.
